(19) United States
(12) Patent Application Publication
(10) Pub. No.: US 2024/0176494 A1
(43) Pub. Date: May 30, 2024

(54) MEMORY DEVICE PERFORMING READ OPERATION AND METHOD OF OPERATING THE SAME

(71) Applicant: SK hynix Inc., Icheon-si Gyeonggi-do (KR)

(72) Inventors: Jae Yeop JUNG, Icheon-si Gyeonggi-do (KR); Dong Hun KWAK, Icheon-si Gyeonggi-do (KR)

(73) Assignee: SK hynix Inc., Icheon-si Gyeonggi-do (KR)

(21) Appl. No.: 18/318,546

(22) Filed: May 16, 2023

(30) Foreign Application Priority Data
Nov. 30, 2022 (KR) 10-2022-0164912

(51) Int. Cl. G06F 3/06

(52) U.S. Cl. CPC G06F 3/0613; G06F 3/0659; G06F 3/0679

(57) ABSTRACT

A memory device includes a memory cell array comprising a plurality of regions. Each region is a segment or portion of a page. Each region is connected to dummy word lines and word lines. A voltage generator provides a read voltage for reading a memory cell connected to a selected word line, and provides a pass voltage for turning on a dummy memory cell included in a region corresponding to the selected region. A read operation controller controls the voltage generator to apply the pass voltage to the dummy word lines and apply the read voltage to the selected word line.

### CROSS-REFERENCE TO RELATED APPLICATION

The present application claims priority under 35 U.S.C. § 119(a) to Korean patent application number 10-2022-0164912 filed on Nov. 30, 2022, in the Korean Intellectual Property Office, the entire disclosure of which is incorporated by reference herein.

### BACKGROUND

### 1. Field of Invention

The present disclosure relates to an electronic device, and more particularly, to a memory device performing a read operation. The present disclosure also relates to a storage device, which comprises one or more memory devices, as well as a memory controller.

### 2. Description of Related Art

A storage device is considered herein to be a device comprised of memory devices, which store data under control of a host device, such as a computer or a smart phone. A storage device may include one or more memory devices, in which data is stored. A storage device may also comprise a memory controller controlling the one or more memory devices.

In response to a read request requesting the stored data, a memory device of a storage device “reads” a page in which the requested data is stored. The memory device then transfers the read data to the host. Meanwhile, the memory device may receive a read request (for example, 4 KB Read) for a portion of one page. Even in a case of a read request for a partial page, the memory device will inefficiently perform a read operation for the partial page in a method that senses an entire page and but which outputs only the requested, partial page of data.

### SUMMARY

An embodiment of the present disclosure provides a memory device and a method of operating the same supporting an improved partial read operation.

According to an embodiment of the present disclosure, a memory device includes a memory cell array including a plurality of regions connected to each of a plurality of dummy word lines and a plurality of word lines, a voltage generator configured to generate a read voltage for reading a memory cell connected to the selected word line, when a read request for a selected word line among the plurality of word lines and a selected region among the plurality of regions is received, a pass voltage for turning on a dummy memory cell included in a region corresponding to the selected region, and a read operation controller configured to control the voltage generator to apply the pass voltage to the plurality of dummy word lines and apply the read voltage to the selected word line.

According to an embodiment of the present disclosure, a storage device comprises a memory controller configured to transmit a command and an address to perform a quarter read operation, a memory cell array comprising a plurality of dummy word lines and a plurality of word lines, a voltage generator configured to, generate a read voltage applied to the word line and generate a pass voltage for turning on dummy memory cells corresponding to the region, when a word line among the plurality of word lines and a region among a plurality of regions are selected by the address; and a read operation controller configured to, in response to the command, control the voltage generator to apply the pass voltage to the plurality of dummy word lines and the read voltage to the selected word line.

According to an embodiment of the present disclosure, a method of operating a memory device including a plurality of dummy word lines and a plurality of word lines divided into a first region to a fourth region comprises: programming the plurality of dummy word lines to correspond to any one among the first region to the fourth region, receiving a quarter read request for any one region among the first region to the fourth region of a selected word line, applying a pass voltage for turning on dummy memory cells corresponding to the any one region to the plurality of dummy word lines, and applying a read voltage to the selected word line.

According to the present technology, a memory device and a method of operating the same supporting an improved partial read operation are provided.

### BRIEF DESCRIPTION OF THE DRAWINGS

FIG. 1 is a block diagram illustrating a storage device according to an embodiment.

FIG. 2 is a diagram illustrating a read operation according to an embodiment.

FIG. 3 is a diagram illustrating a plurality of dummy word lines according to an embodiment.

FIG. 4 is a diagram illustrating a quarter read operation in detail according to an embodiment.

FIG. 5 is a diagram illustrating a data pattern according to an embodiment.

FIGS. 6 to 9 are diagrams illustrating a method of applying a pass voltage to a dummy word line during a quarter read operation according to an embodiment.

FIG. 10 is a diagram illustrating a method of operating a memory device according to an embodiment.

### DETAILED DESCRIPTION

Specific structural or functional descriptions of embodiments according to the concept of the present disclosure disclosed in the present specification or application are illustrated only to describe the embodiments according to the concept of the present disclosure. The embodiments according to the concept of the present disclosure may be carried out in various forms and are not limited to the embodiments described in the present specification or application.

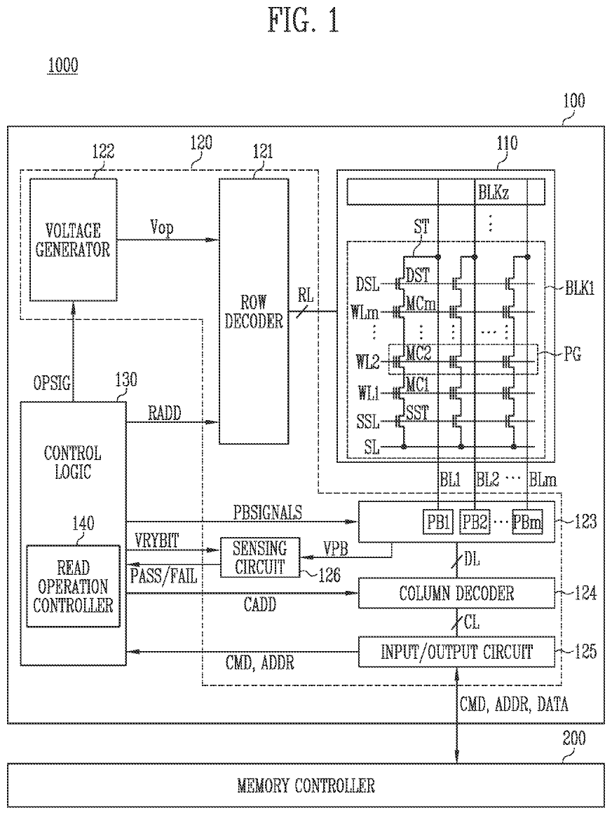

FIG. 1 is a block diagram illustrating a storage device according to an embodiment.

The storage device 1000 may be a device that stores data under control of a host, not shown in FIG. 1. The storage device 1000 may be implemented as any one of various types of storages devices such as a multi-media card, a secure digital card, a universal serial bus (USB) storage device, a universal flash storage (UFS) device, a peripheral component interconnect express (PCI-E) card type of device, and a compact flash (CF) card. A host may be an electronic device such as a mobile phone, a smart phone, an MP3 player, a laptop computer, a desktop computer, a game console, a display device, a tablet PC, or an in-vehicle infotainment system. The storage device 1000 may be mounted inside the host or implemented as an external electronic device of the host.

The storage device 1000 according to an embodiment may include a memory device 100 and a memory controller 200. The memory device 100 may include a memory cell array 110, a peripheral circuit 120, and control logic 130.

The memory device 100 may store data. The memory device 100 may output data stored in the memory device 100. For example, when the memory controller 200 transmits a read command and an address to the memory device 100, the memory device 100 may perform a read operation to output data stored in a page of the memory device 100 corresponding to the address to memory controller 200.

The memory cell array 110 may include a plurality of memory blocks BLK1 to BLKz. Here, for convenience of description, a first memory block BLK1 among the plurality of memory blocks BLK1 to BLKz is described and is an exemplar or representative of other memory blocks. A description of the first memory block BLK1 is therefore applicable to other memory blocks.

As shown in FIG. 1, the first memory block BLK1 may be connected to a row decoder 121 through a row line RL. The row line RL, may include at least one source select line SSL, a plurality of word lines WL1 to WLm, at least one drain select line DSL and a common source line SL. The first memory block BLK1 may be connected to a group of page buffers PB1 to PBm, which is also referred to herein as a page buffer group 123, through bit lines BL1 to BLm. The first memory block BLK1 may include a plurality of memory cells MC1 to MCm. In an embodiment, the plurality of memory cells MC1 to MCm may be nonvolatile memory cells. Memory cells connected to the same word line i.e., any one of the plurality of word lines WL1 to WLm, may be defined as a page, PG. That is, each memory block of the plurality of memory blocks BLK1 to BLKz, may include a plurality of pages. Each memory cell of the plurality of memory cells MC1 to MCm may be configured as a single level cell (SLC), which stores one data bit, a multi-level cell (MLC), which stores two data bits, a triple level cell (TLC), which stores three data bits, or a quad level cell (QLC), which stores four data bits.

In FIG. 1, a peripheral circuit 120 comprises a row decoder 121, a voltage generator 122, a page buffer group 123, a column decoder 124, an input/output circuit 125 and a sensing circuit 126. The peripheral circuit 120 may be configured to perform a program operation, a read operation, or an erase operation on a selected region of the memory cell array 110 under control of the control logic 130. For example, the peripheral circuit 120 may apply various operation voltages to the row line RL and the bit lines BL1 to BLm or the peripheral circuit 120 may discharge applied voltages under the control of the control logic 130.

As stated above, the row decoder 121 may be connected to the memory cell array 110 through the row line RL. In an embodiment, the plurality of word lines WL1 to WLm, may include a normal word line and a dummy word line. The row decoder 121 may select at least one memory block among the memory blocks BLK1 to BLKz and at least one word line among the plurality of word lines WL1 to WLm according to a row address RADD received from control logic 130, which is embodied as either combinational and sequential logic devices or a functionally-equivalent processor, neither of which are shown in the interest of brevity. In addition, the row decoder 121 may apply the voltage generated by the voltage generator 122 to a selected word line of a selected memory block.

The voltage generator 122 may generate an operation voltage Vop, the magnitude of which can be varied in response to an operation signal OPSIG received from the control logic 130. The magnitudes of the operation voltages Vop are thus selected or programmed by a signal from the control logic 130 are thus considered herein as being selectable or programmable. As shown in FIG. 1, the voltage generator 122 may generate the operation voltage Vop based on a supply voltage received from an external power source. The operation voltages Vop produced by the voltage generator 122 include but are not limited to a program voltage, a verify voltage, a pass voltage, a read voltage, a read pass voltage, an erase voltage, and the like, each of which may be of different magnitudes.

The page buffer group 123 may include a plurality of page buffers PB1 to PBm. Each of the plurality of page buffers PB1 to PBm may be connected to the memory cell array 110 through corresponding bit lines BL1 to BLm. A page buffer group 123 may operate in response to the control signal PBSIGNALS output from the control logic 130. For example, a first page buffer PB1 may temporarily store data received through a first bit line BL1 or sense a voltage or a current of the first bit line BL1 during a read or verify operation. In an embodiment, during the read operation, the first page buffer PB1 may read data DATA from memory cells of a selected page through the first bit line BL1 and output the data DATA obtained from or provided by the selected page, to the input/output circuit 125. In the interest of brevity, the operation of the first page buffer PB1 as described above is applicable to other page buffers.

The column decoder 124 may transfer the data (DATA) between the input/output circuit 125 and the page buffer group 123 in response to a column address, CADD. For example, the column decoder 124 may exchange the data with the first to m-th page buffers PB1 to PBm through data line DL, or may exchange the data with the input/output circuit 125 through a column line CL.

The input/output circuit 125 may transfer a command CMD and an address ADDR received from the memory controller 200 to the control logic 130, or may exchange the data DATA with the column decoder 124. For example, during the read operation, the input/output circuit 125 may receive the data DATA read from the memory block from the page buffer group 123 and transmit the data DATA to the memory controller 200.

During the read operation or a verify operation, the sensing circuit 126 may generate a reference current in response to an allowable bit signal VRYBIT, and thereafter output a pass signal PASS or a fail signal FAIL according to a result of comparing a sensing voltage VPB received from the page buffer group 123, to a reference voltage, generated by the reference current from the sensing circuit 126.

As shown in FIG. 1, the control logic 130 may output an operation signal OPSIG to the voltage generator 122, output a row address RADD to the row decoder 121, output page buffer control signals PBSIGNALS to the page buffer group 123, and output the bit signal VRYBIT, all in response to a command CMD and an address ADDR that the control logic 130 receives from the input/output circuit 125, by which the control logic 130 controls or determines operation of the peripheral circuit 120.

In an embodiment, the control logic 130 may include a read operation controller 140. The read operation controller 140 may control the peripheral circuit 120 to perform a read operation for at least a portion of data stored in one page. The read operation may be one of a normal read operation and a quarter read operation. A normal read operation is a read operation whereby all of the data stored in a selected page (that is, the entire region included in the selected page) is read and provided to the memory controller 200. A quarter read operation is a read operation for part or some of the data of stored in the selected page (that is, a partial region of the entire region included in the selected page) and provide to the memory controller 200. For example, a quarter read operation may refer to a read operation for any one of a first region to a fourth region. A region may be a portion of a page that is determined by dividing an entire page into a plurality of regions. The plurality of regions may have equal or substantially-equal size as each other. In other example, the plurality of regions may have different sizes as each other.

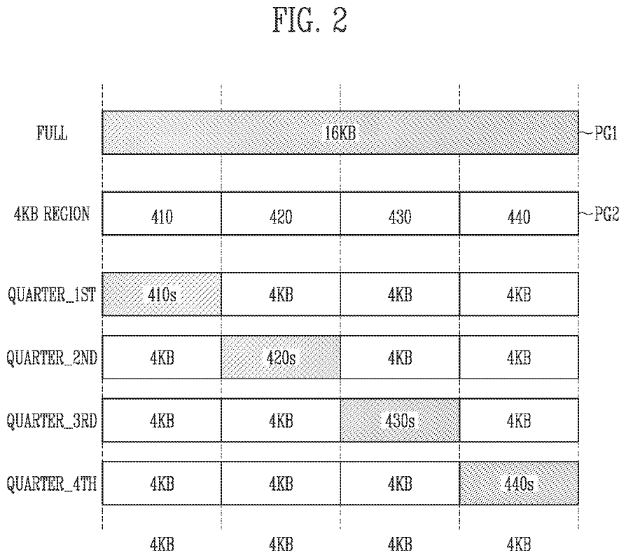

FIG. 2 is a diagram illustrating a read operation according to an embodiment.

Referring to FIGS. 1 and 2, the read operation controller 140 may control the peripheral circuit 120 to perform a read operation by reading data from at least a region 410, 420, 430 or 440 of a selected page among a plurality of pages. Here, the selected page is a page selected by an address ADDR, provided to the memory device 100 by the memory controller 200 and hence the memory array 110. Hereinafter, it is assumed that a first page PG1 among the plurality of pages is the selected page. The first page PG1 may be divided into a plurality of regions 410 to 440. For example, in FIG. 2, the first page PG1 may comprise four regions 410 to 440. Each region of the plurality of regions 410 to 440 may include a plurality of memory cells connected to the same word line. The read operation may comprise a voltage application operation of applying a read voltage to a selected word line, applying a read pass voltage to an unselected word line, and a sensing operation of sensing a current flowing through a bit line according to the read voltage to identify whether the memory cell is an on cell or an off cell.

The read operation may be one of a normal read operation or a quarter read operation. The normal read operation is an operation that reads data from an entire region of the first page PG1, selected by the address ADDR, received from the memory controller 200. A quarter read operation is an operation that reads data from a region of the first page PG1, selected by the address ADDR. For example, a first quarter read operation may be an operation that reads data from a first selected region 410s of the first page PG1. A second quarter read operation may be an operation that reads data from a second selected region 420s of the first page PG1. A third quarter read operation may be an operation that reads data from a third selected region 430s of the first page PG1. A fourth quarter read operation may be an operation that reads data from a fourth selected region 440s of the first page PG1.

In an embodiment, when the command CMD and the address ADDR indicating a normal read request are received by the control logic 130, the read operation controller 140 may control the peripheral circuit 120 to perform the normal read operation for the entire region of the first page PG1, i.e, all of the regions 410, 420, 430 and 440 of the first page PG1, indicated by the address ADDR. For example, when 16 KB of data is stored in one page, the peripheral circuit 120 may read 16 KB of data from the entire region of one page within the memory array 110.

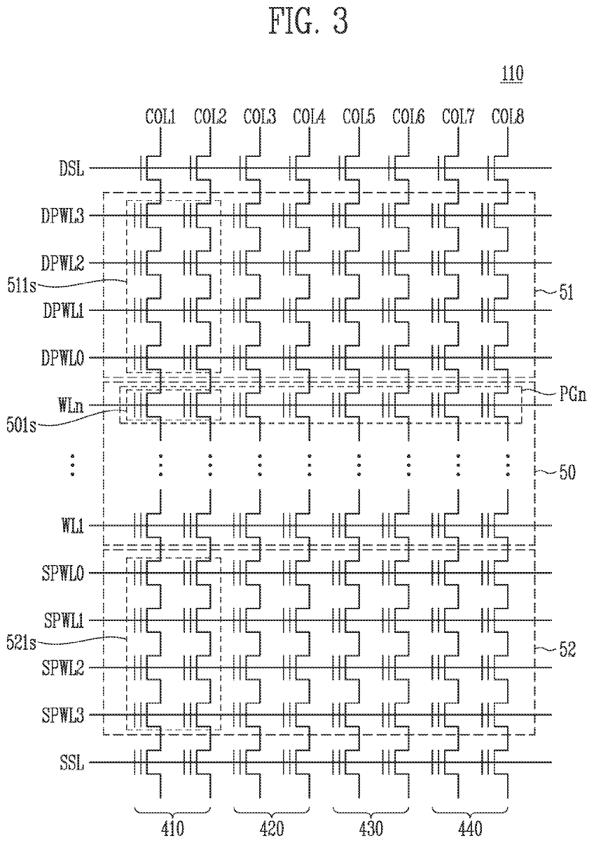

In an embodiment, when the command CMD and the address ADDR indicating a quarter read request are received from the memory controller 200, the read operation controller 140 (within and part of the logic circuit 130) may control the peripheral circuit 120 to perform the quarter read operation for a partial region, i.e., one of a first region 410, a second region 420, a third region 430 or a fourth region, 440, which together, comprise the first page PG1, indicated by the address ADDR. A partial region of the first page PG1 may be one of the plurality of regions 410 to 440. Here, the address ADDR may include information for selecting a specific page and a specific region of the specific page. For example, when 16 KB of data is stored in one page, each of the four regions 410 to 440 may store 4 KB of data. The peripheral circuit 120 may read 4 KB of data from one region among a plurality of regions included in one page. To this end, different data may be programmed in dummy memory cells for each dummy word line and region using a data coding method. For example, the data coding method may be one of SLC, MLC, TLC and QLC. For example, the memory cell may be a flash memory cell that stores user data, and the dummy memory cell may be a flash memory cell that stores data for selectively activating a specific region. The dummy word line is specifically described with reference to FIG. 3.

FIG. 3 is a diagram illustrating a plurality of dummy word lines according to an embodiment.

Referring to FIGS. 2 and 3, the memory cell array 110 may be connected to a plurality of dummy word lines SPWL0 to SPWL3 and DPWL0 to DPWL3 and a plurality of word lines WL1 to WLn. In an embodiment, the memory cell array 110 may further include a drain select line DSL and a source select line SSL.

The memory cell array 110 may include a plurality of memory cells 50 and a plurality of dummy memory cells 51 and 52. The plurality of memory cells 50 and the plurality of dummy memory cells 51 and 52 may be divided into a plurality of regions 410, 420, 430 and 440. That is, the memory cell array 110 may include the plurality of regions 410 to 440, and each of the regions 410 to 440 may include at least one memory cell and at least one dummy memory cell. Here, each of the regions 410 to 440 may be referred to as a cell group. For example, a first region 410 may include a memory cell 50 and a dummy memory cell comprising or corresponding to both a first column, COL1 and a second column, COL2. A second region 420 may include a memory cell and a dummy memory cell comprising or corresponding to a third column, COL3 and a fourth column, COL4. A third region 430 may include a memory cell and a dummy memory cell corresponding to a fifth column COL5 and a sixth column, COL6. A fourth region 440 may include a memory cell and a dummy memory cell corresponding to a seventh column, COL7 and an eighth column, COL8. However, this is only an example, and the number of memory cells and dummy memory cells included in each region may be changed in various numbers.

Each of the plurality of dummy word lines SPWL0 to SPWL3 and DPWL0 to DPWL3 may be connected to dummy memory cells 51 and 52. Each of the plurality of word lines WL1 to WLn may be connected to a memory cell 50. The memory cell 50 may be connected between the dummy memory cells 51 and 52.

In an embodiment, the plurality of dummy word lines SPWL0 to SPWL3 and DPWL0 to DPWL3 may include source dummy word lines SPWL0 to SPWL3 and drain dummy word lines DPWL0 to DPWL3. Drain dummy word lines DPWL0 to DPWL3 may be connected to a first dummy memory cell 51. The first dummy memory cell 51 may be positioned between a memory cell 50 connected to the drain select line DSL and a plurality of memory cells 50 connected to the plurality of word lines WL1 to WLn. Source dummy word lines SPWL0 to SPWL3 may be connected to a second dummy memory cell 52. The second dummy memory cell 52 may be positioned between a memory cell 50 connected to the source select line SSL and the plurality of memory cells 50 connected to the plurality of word lines WL1 to WLn.

In an embodiment, a plurality of dummy word lines SPWL0 to SPWL3 and DPWL0 to DPWL3 may include first to fourth drain dummy word lines DPWL0 to DPWL3 and first to fourth source dummy word lines SPWL0 to SPWL3. That is, the number of drain dummy word lines DPWL0 to DPWL3 may be four, and the number of source dummy word lines SPWL0 to SPWL3 may be four. However, this is only an example and may be modified and implemented in various numbers. Hereinafter, the disclosure is described under an assumption that the number of dummy word lines SPWL0 to SPWL3 and DPWL0 to DPWL3 is four as shown in FIG. 3.

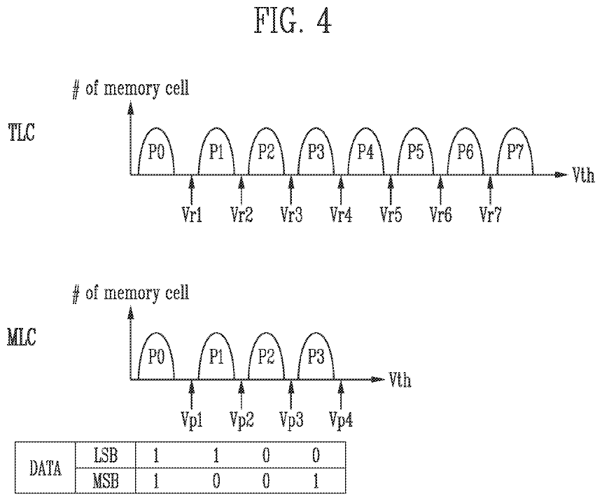

In an embodiment, the dummy memory cells 51 and 52 may be programmed with different data for each dummy word line and region using a data coding method. This is to selectively activate a specific region among a plurality of regions by programming different data. Accordingly, during the quarter read operation, data stored in a partial region rather than the entire region of the page may be read and provided to the memory controller 200. An example of the quarter read operation is described with reference to FIG. 4.

FIG. 4 is a diagram illustrating a quarter read operation in detail according to an embodiment.

Referring to FIGS. 3 and 4, each of the memory cells 50 connected to the word lines WL1 to WLn and the dummy memory cells 51 and 52 connected to the dummy word lines SPWL0 to SPWL3 and DPWL0 to DPWL3 may be programmed through a data coding method. For example, the memory cell may be programmed to store user data according to a TLC method, and the dummy memory cells 51 and 52 may be programmed to store dummy data according to an MLC method. However, this is only an example and each data coding method may be variously modified and implemented.

In an embodiment, the read operation controller 140 may control the peripheral circuit 120 to perform the quarter read operation of reading data stored in a partial region rather than the entire region of a page using the dummy memory cells 51 and 52 programmed with different data for each dummy word line and region. That is, a magnitude of the pass voltage for turning on the dummy memory cells 51 and 52 may vary for each dummy word line and region. During the quarter read operation, a channel of a selected region may be activated and a channel of an unselected region may be inactivated according to a magnitude relationship between the pass voltages applied to the plurality of dummy word lines SPWL0 to SPWL3 and DPWL0 to DPWL3 and a threshold voltage of the dummy memory cells 51 and 52. In this case, the channel of the unselected region may be floated.

To this end, the dummy memory cells 51 and 52 may be programmed to have an MLC method of threshold voltage distribution. The dummy memory cells 51 and 52 may have one program state among a plurality of program states P0 to P3 according to a threshold voltage. Among the plurality of program states P0 to P3, a 0-th program state P0 may be an erase state corresponding to a threshold voltage of a case where the erase operation is performed.

For example, from among dummy memory cells 511s and 521s included in a first region 410, data programmed in dummy memory cells connected to first dummy word lines DPWL0 and SPWL0 and data programmed in dummy memory cells connected to second to fourth dummy word lines DPWL1 to DPWL3 and SPWL1 to SPWL3 may be different from each other. In addition, from among dummy memory cells connected to the first dummy word lines DPWL0 and SPWL0, data programmed in dummy memory cells included in the first region 410 and data programmed in dummy memory cells included in another region may be different from each other.

As a specific example, it is assumed that the dummy memory cells of the first region 410 and the first dummy word lines DPWL0 and SPWL0 are programmed to the 0-th program state P0, and the dummy memory cells of the first region 410 and second to fourth dummy word lines DPWL1 to DPWL3 and SPWL1 to SPWL3 are programmed to any one of first to third program states P1 to P3.

During the quarter read operation, under control of the read operation controller 140, the voltage generator 122 may apply a first pass voltage Vp1 greater than a threshold voltage corresponding to the 0-th program state P0 to the first dummy word lines DPWL0 and SPWL0, and apply a fourth pass voltage Vp4 greater than a threshold voltage corresponding to the third program state P3 to the second to fourth dummy word lines DPWL1 to DPWL3 and SPWL1 to SPWL3. In this case, the first region 410 may be activated. Specifically, the dummy memory cells 511s and 521s included in the first region 410 among the dummy memory cells connected to the first to fourth dummy word lines DPWL0 to DPWL3 and SPWL0 to SPWL3 may be turned on.

In this case, the read operation controller 140 may control the peripheral circuit 120 to apply read voltages Vr1 to Vr7 to the selected word line (or the selected page) and apply the read pass voltage to the unselected word line (or an unselected page). For example, referring to FIG. 3, the selected word line may be the n-th word line WLn and the selected page may be the n-th page PGn. Here, it is assumed that the memory cell included in the selected page is already programmed to have a TLC method of threshold voltage distribution. A memory cell included in the selected page may have one program state among a plurality of program states P0 to P7 according to a threshold voltage. That is, data stored in memory cells 501s included in the activated region from among a plurality of regions of the selected page may be acquired as a result of the quarter read operation.

In a specific embodiment, the voltage generator 122 may generate read voltages Vr1 to Vr7, each voltage having a different magnitude in order to distinguish a programmed state of the memory cell in response to the operation signal OPSIG of the read operation controller 140. The row decoder 121 may apply the read voltages Vr1 to Vr7 to the selected word line of the selected memory block indicated by the row address RADD of the read operation controller 140, and apply the read voltage higher than the read voltage to the unselected word line of the selected memory block. Here, a memory cell included in an activated region may be turned on or off according to a magnitude relationship of the threshold voltage and the read voltages Vr1 to Vr7 of the memory cell included in the activated region of the selected page connected to the selected word line. In addition, the plurality of page buffers of the page buffer group 123 may identify the program state of the memory cell according to a voltage or a current received from a corresponding bit line.

For example, when the memory cell is programmed to a fourth program state P4, a level of a threshold voltage of a corresponding memory cell may be greater than a level of first to fourth read voltages Vr1 to Vr4 and less than fifth to seventh read voltages Vr5 to Vr7.

In this case, when the first to fourth read voltages Vr1 to Vr4 are applied to word lines connected to a corresponding memory cell, and another memory cell connected to another word line and the dummy memory cell connected to the dummy word line are turned on, a page buffer connected to the corresponding memory cell may identify that the corresponding memory cell is the off cell because a current does not flow through a bit line connected therebetween. When the fifth to seventh read voltages Vr5 to Vr7 are applied to the word line connected to the corresponding memory cell, and another memory cell connected to another word line and the dummy memory cell connected to the dummy word line are turned on, the page buffer connected to the corresponding memory cell through the bit line may identify that the corresponding memory cell is the on cell because a current flows through the connected bit line.

The read operation controller 140 or the page buffer may identify that the corresponding memory cell is programmed to a fourth program state P4 by combining a result of applying the first to seventh read voltages Vr1 to Vr7. Here, each of the plurality of program states may correspond to a preset data value. According to the present disclosure, data corresponding to a program state of each of the plurality of memory cells 50 may be obtained in the method described above.

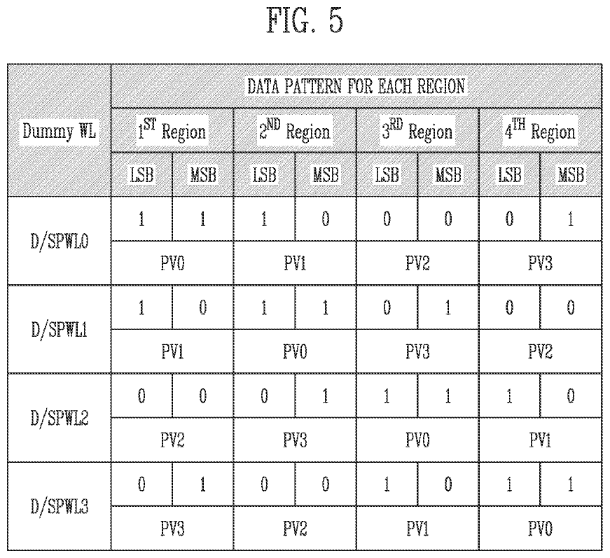

FIG. 5 is a diagram illustrating a data pattern according to an embodiment.

Referring to FIGS. 4 and 5, a program state and data of the dummy memory cells according to the dummy word line and the region are shown. Here, a plurality of regions may include first to fourth regions of a particular page. The program state may be one of 0-th to third program states P0 to P3 and PV0 to PV3 according to an MLC method. Meanwhile, the data pattern of FIG. 5 may be modified in various forms and implemented.

In an embodiment, a dummy memory cell included in one dummy word line D/SPWL0 to D/SPWL3 may be programmed to be in different program states for each region. The dummy memory cell included in one dummy word line D/SPWL0 to D/SPWL3 may be programmed to be in the same program state in the same region.

In an embodiment, a first dummy memory cell connected to a first dummy word line D/SPWL0 and included in a first region may be programmed with first data, a second dummy memory cell connected to the first dummy word line D/SPWL0 and included in a second region may be programmed with second data. Here, the first data may be data different from the second data. For example, the first data may be a value of ‘11’ and the second data may be a value of ‘10’. The value of ‘11’ may be preset to correspond to the 0-th program states P0 and PV0, and the value of ‘10’ may be preset to correspond to the first program states P1 and PV1. As described above, among the dummy memory cells connected to the same dummy word line, data programmed in dummy memory cells included in different regions may be different from each other.

In an embodiment, a dummy memory cell included in one region of any one dummy word line D/SPWL0 to D/SPWL3 may be programmed to be in a program state, different from that of a dummy memory cell included in the same region of another dummy word line. For example, first data connected to the first dummy word line D/SPWL0 and programmed in a first dummy memory cell included in a first region may be data different from third data connected to a second dummy word line D/SPWL1 and a third dummy memory cell included in the first region. As described above, among dummy memory cells included in the same region, data programmed in dummy memory cells connected to different dummy word lines may be different from each other.

That is, the 0-th program states P0 and PV0 of the first dummy memory cell connected to the first dummy word line D/SPWL0 and included in the first region may be different from a program state of dummy memory cell included in the first region connected to the second dummy word line D/SPWL1 to the fourth dummy word line D/SPWL3.

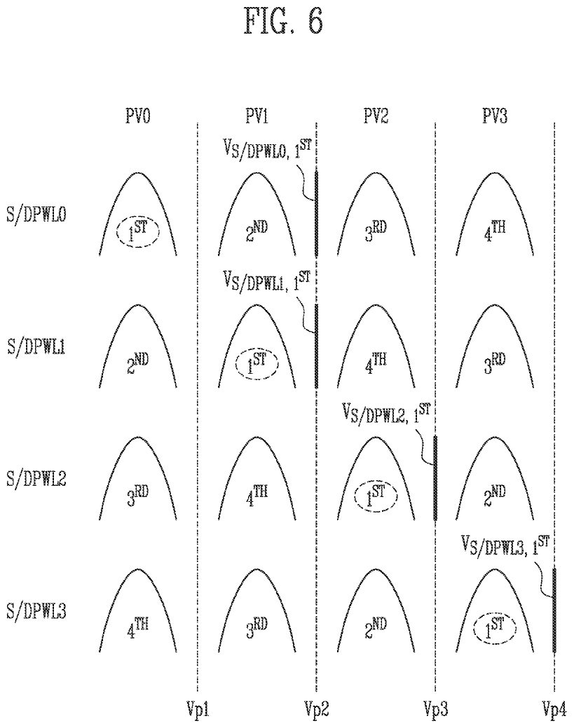

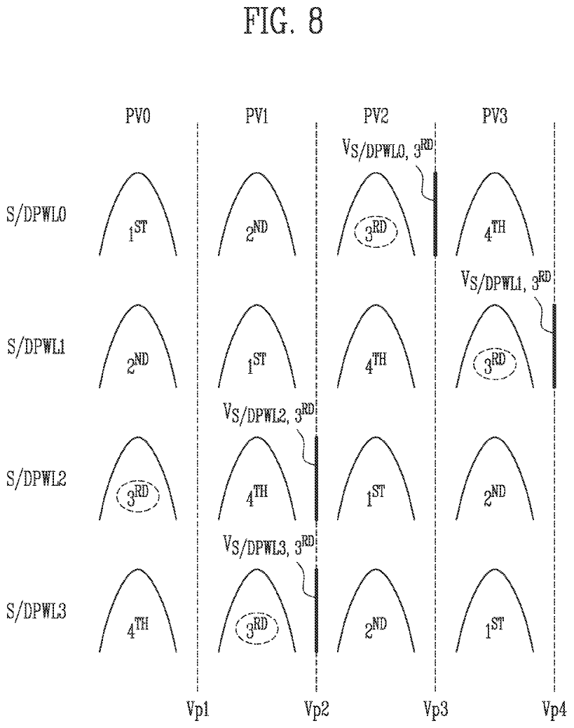

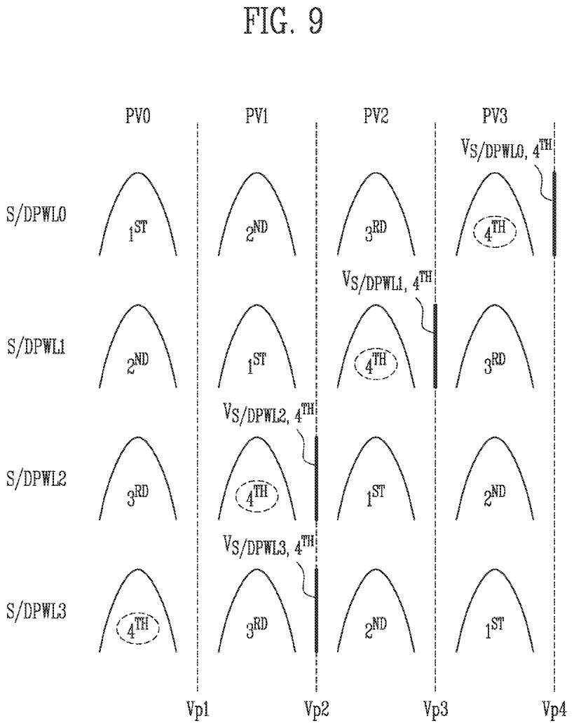

In accordance with the present disclosure, according to a data pattern stored in the dummy memory cell and the pass voltage applied to the dummy word line, the page may divided into the plurality of regions, only one region may be activated, and the quarter read operation for the activated region may be performed. Hereinafter, it is assumed that data is stored in the dummy memory cell in the data pattern shown in FIG. 5 and the pass voltage is specifically described with reference to FIGS. 6 to 9.

FIGS. 6 to 9 are diagrams illustrating a method of applying a pass voltage to a dummy word line during a quarter read operation according to an embodiment.

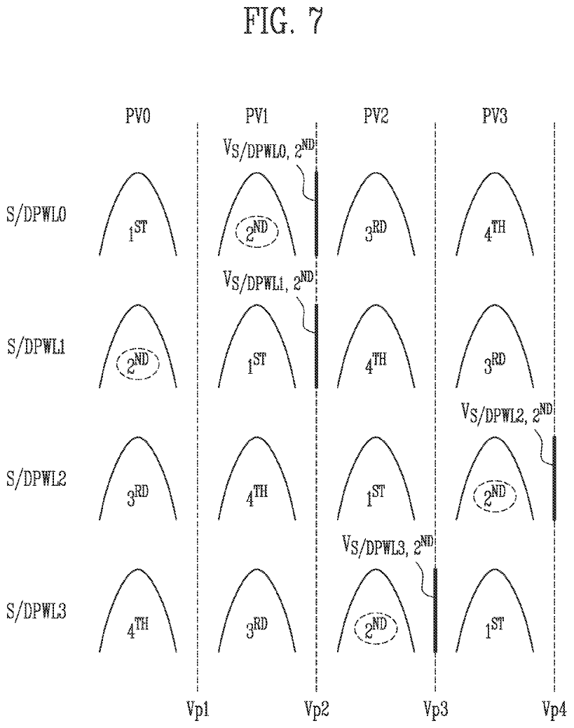

FIG. 6 is a threshold voltage distribution of dummy memory cells included in the first region, and FIGS. 7 to 9 illustrate a threshold voltage distribution of the dummy memory cells included in the second region to the fourth region.

In an embodiment, the dummy memory cell may be programmed to have different program states according to a dummy word line to which the corresponding dummy memory cell is connected and a region in which the corresponding dummy memory cell is included. For example, a first dummy memory cell included in a first region connected to a first dummy word line S/DPWL0 may be programmed to have the 0-th program state PV0, a second dummy memory cell included in a first region connected to a second dummy word line S/DPWL1 may be programmed to have the first program state PV1, a third dummy memory cell included in a first region connected to a third dummy word line S/DPWL2 may be programmed to have the second program state PV2, and a fourth dummy memory cell included in a first region connected to a fourth dummy word line S/DPWL3 may be programmed to have the third program state PV3.

In an embodiment, the read operation controller 140 may control the voltage generator to apply pass voltages of different magnitudes to at least two dummy word lines among the plurality of dummy word lines S/DPWL0 to S/DPWL3.

In a specific embodiment, when the read operation controller 140 receives a command and an address according to the quarter read request for the first region among the plurality of regions included in the selected word line from the memory controller, during the quarter read operation, the read operation controller 140 may control the voltage generator to apply a pass voltage of a preset or predetermined magnitude to turn on the dummy memory cell included in the first region connected to each of first to fourth dummy word lines S/DPWL0 to S/DPWL3 to each of the first to fourth dummy word lines S/DPWL0 to S/DPWL3. For example, a second pass voltage Vp2 may be applied to the first dummy word line S/DPWL0, and second to fourth pass voltages Vp2 to Vp4 may be applied to the second to fourth dummy word lines S/DPWL1 to S/DPWL3, respectively.

The magnitude of the pass voltage applied to each of the first to fourth dummy word lines S/DPWL0 to S/DPWL3 may be greater than the magnitude of a threshold voltage of the dummy memory cell included in the first region of each of the first to fourth dummy word lines S/DPWL0 to S/DPWL3. Accordingly, the dummy memory cell included in the first region of each of the first to fourth dummy word lines S/DPWL0 to S/DPWL3 may be turned on. That is, the first region may be activated. For example, the second pass voltage Vp2 is applied to the first dummy word line S/DPWL0, and the second pass voltage Vp2 is a voltage having a level, i.e., magnitude, greater than a threshold voltage belonging to the 0-th program state PV0 of the dummy memory cell included in the first region of the first dummy word line S/DPWL0.

As described above, when one region is selected from among the plurality of regions by the address and the quarter read operation for the selected region is performed, each pass voltage for activating the selected region may be applied to the first to fourth dummy word lines S/DPWL0 to S/DPWL3. As shown in FIGS. 7 to 9, when one of the second to fourth regions is selected, a pass voltage having a level greater than a threshold voltage of a dummy memory cell included in the selected region may be applied to the first to fourth dummy word lines S/DPWL0 to S/DPWL3 in a method equal to that described above with reference to FIG. 6.

In an embodiment, when one region is selected from among the plurality of regions, the selected region may be activated and a remaining region may be inactivated, except for the selected region.

For example, when the first region is selected by the address, as shown in FIG. 6, the second pass voltage Vp2 may be applied to the first dummy word line S/DPWL0, the second to fourth pass voltages Vp2 to Vp4 may be applied to the second to fourth dummy word lines S/DPWL1 to S/DPWL3, and thus the first region may be activated. At this time, as shown in FIG. 7, in a case of a second region, since the threshold voltage of the dummy memory cell of the second region of the first dummy word line S/DPWL0 belongs to the first program state PV1 and has a level less than that of the second pass voltage Vp2, the dummy memory cell of the second region of the first dummy word line S/DPWL0 is turned on. Similarly to this, the dummy memory cells of the second region of the second dummy word line S/DPWL1 are turned on. On the other hand, since the threshold voltage of the dummy memory cell of the second region of the third dummy word line SDPWL2 belongs to the third program state PV3 and has a level higher than that of the second pass voltage Vp2, the dummy memory cell of the second region of the third dummy word line S/DPWL2 is turned off. Similarly, the dummy memory cell of the second region of the fourth dummy word line S/DPWL3 is turned off. As described above, the second region may be floated and inactivated. The third region and the fourth region may also be inactivated in such a method.

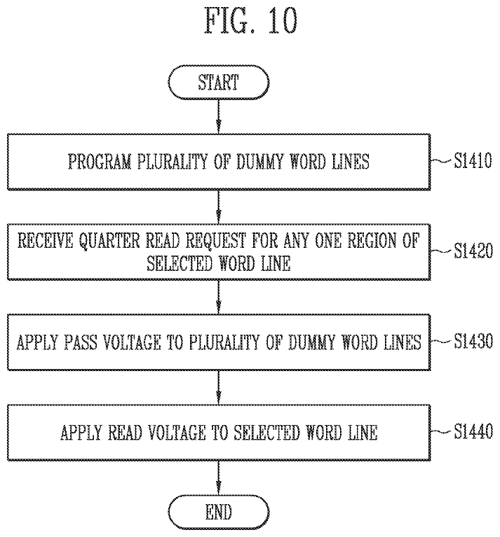

FIG. 10 is a diagram illustrating a method of operating a memory device according to an embodiment.

Referring to FIG. 10, a method of operating the memory device 100 including the plurality of dummy word lines and the plurality of word lines divided into the first to fourth regions is shown.

First, the memory device 100 may program the plurality of dummy word lines (S1410). Specifically, the memory device 100 may program the plurality of dummy word lines to correspond to any one of the first region to the fourth region. Here, the first region to the fourth region may be divided according to a logical address.

According to an embodiment of the present disclosure, the memory device 100 may program the plurality of dummy word lines so that different data is stored for each dummy word line. In addition, when the memory device 100 receives a read request for a specific region of a word line, the memory device 100 may apply the pass voltage to turn on dummy memory cells corresponding to the specific region. The plurality of dummy word lines may be programmed to store different data, and the pass voltages applied to the plurality of dummy word lines may be different from each other.

In addition, the memory device 100 may receive the quarter read request for any one region of the selected word line (S1420). For example, the word line included in the memory device 100 may be divided into the first region to the fourth region according to the logical address. In addition, the memory device 100 may receive the quarter read request for any one region among the first region to the fourth region of the selected word line. That is, the quarter read request may be a request requesting the data stored in the specific region of the selected word line.

In addition, the memory device 100 may apply the pass voltage to the plurality of dummy word lines (S1430). Specifically, the memory device 100 may apply the pass voltage for turning on the dummy memory cells corresponding to any one region among the dummy memory cells included in the plurality of dummy word lines to the plurality of dummy word lines. Pass voltages applied to each of the plurality of dummy word lines may be different from each other. Meanwhile, the memory device 100 may float channels corresponding to remaining regions except for any one region requested by the host. In addition, the memory device 100 may apply the pass voltage for turning on the memory cells corresponding to the unselected word line to the unselected word line.

In addition, the memory device 100 may apply the read voltage to the selected word line (S1440). The memory device 100 may sense data stored in the selected word line by applying the read voltage to the selected word line, and output a sensed result. Meanwhile, the memory device 100 may pre-charge a bit line corresponding to the dummy memory cells corresponding to any one region of the selected word line.

Those of ordinary skill in the art should appreciate that, among other things, the time required to apply a pass voltage can be reduced by the embodiments of the present disclosure and equivalents thereof. A memory device 100 may perform a read operation for a selected region of a selected word line, and the channel corresponding to the unselected region (remaining region) of the selected word line may be floated, thereby reducing the time in which a pass voltage is applied.

What is claimed is:

1. A memory device comprising:
a memory cell array including a plurality of regions connected to each of a plurality of dummy word lines and a plurality of word lines;
a voltage generator configured to, generate a read voltage for reading a memory cell connected to a selected word line, and generate a pass voltage for turning on a dummy memory cell included in a region corresponding to a selected region, when a read request for the selected word line among the plurality of word lines and the selected region among the plurality of regions, are received; and
a read operation controller configured to, control the voltage generator to apply the pass voltage to the plurality of dummy word lines and apply the read voltage to the selected word line, in response to the read request.

2. The memory device of claim 1, wherein a plurality of dummy memory cells included in one of the plurality of regions are connected to each of the plurality of dummy word lines, and
the plurality of dummy memory cells are programmed with different data for each dummy word line and region.

3. The memory device of claim 2, wherein first data programmed in a first dummy memory cell connected to a first dummy word line of the plurality of dummy word lines and included in a first region of the plurality of regions, is data different from second data programmed in a second dummy memory cell connected to the first dummy word line and included in a second region of the plurality of regions.

4. The memory device of claim 2, wherein first data programmed in a first dummy memory cell connected to a first dummy word line of the plurality of dummy word lines and included in a first region of the plurality of regions is data different from third data programmed in a third dummy memory cell connected to second dummy word line of the plurality of dummy word lines and included in the first region.

5. The memory device of claim 1, wherein the read operation controller controls the voltage generator to apply pass voltages of different magnitudes to at least two dummy word lines among the plurality of dummy word lines.

6. The memory device of claim 1, wherein at least one dummy memory cell is turned off among dummy memory cells included in a remaining region except for the selected region, when the pass voltage is applied to the plurality of dummy word lines.

7. The memory device of claim 1, wherein the plurality of regions includes first to fourth regions selected by an address received together with the read request, and
the plurality of dummy word lines includes a first dummy word line, a second dummy word line, a third dummy word line, and a fourth dummy word line to which different dummy memory cells are connected.

8. A storage device comprising:
a memory controller configured to transmit a command and an address to perform a quarter read operation;
a memory cell array including a plurality of dummy word lines and a plurality of word lines;
a voltage generator configured to, generate a read voltage that is applied to the word line and generate a pass voltage for turning on dummy memory cells corresponding to the region, when a word line among the plurality of word lines and a region among a plurality of regions are selected by the address; and
a read operation controller configured to, control the voltage generator to apply the pass voltage to the plurality of dummy word lines and the read voltage to the selected word line, in response to the transmitted command.

9. The storage device of claim 8, wherein the plurality of dummy word lines includes a first dummy word line to a fourth dummy word line to which dummy memory cells programmed with different data for each dummy word line are respectively connected.

10. The storage device of claim 9, wherein the read operation controller controls the voltage generator to apply pass voltages of different magnitudes to the first dummy word line to the fourth dummy word line.

11. The storage device of claim 8, wherein when the pass voltage is applied to the plurality of dummy word lines, a channel corresponding to a remaining region except for the one region among the plurality of regions is floated.

12. The storage device of claim 8, wherein the read operation controller controls the voltage generator to apply a pass voltage for turning on a memory cell connected to an unselected word line except for one word line among the plurality of word lines to the unselected word line.

13. A method of operating a memory device including a plurality of dummy word lines and a plurality of word lines divided into a first region to a fourth region, the method comprising:
programming the plurality of dummy word lines to correspond to any one among the first region to the fourth region;
receiving a quarter read request for any one region among the first region to the fourth region of a selected word line;
applying a pass voltage for turning on dummy memory cells corresponding to the any one region to the plurality of dummy word lines; and
applying a read voltage to the selected word line.

14. The method of claim 13, wherein programming comprises programming the plurality of dummy word lines so that different data are stored for each dummy word line.

15. The method of claim 14, wherein applying the plurality of dummy word lines comprises applying different pass voltages for each dummy word line.

16. The method of claim 13, further comprising:
precharging a bit line corresponding to dummy memory cells corresponding to the any one region.

17. The method of claim 13, further comprising:
floating channels corresponding to regions except for the any one region among the first region to the fourth region.

18. The method of claim 13, further comprising:
applying a pass voltage for turning on memory cells corresponding to an unselected word line to the unselected word line.
